(19) United States
(12) Patent Application Publication
(10) Pub. No.: US 2008/0215939 A1
(43) Pub. Date: Sep. 4, 2008

(54) Semiconductor memory device with fail-bit storage unit and method for parallel bit testing

(75) Inventors: Ji-Hyun Ahn, Jeonju-si (KR); Nak-Won Heo, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/068,283

(22) Filed: Feb. 5, 2008

(30) Foreign Application Priority Data
Feb. 8, 2007 (KR) 10-2007-0013159

(51) Int. Cl. G11C 29/10; G06F 11/26

(52) U.S. Cl. 714/719; 714/E11.159

(57) ABSTRACT

There are provided a semiconductor memory device and a method for testing the same, in which when a plurality of semiconductor memory devices are under test, tester equipment can detect which one of the semiconductor memory devices fails without a separate fail memory. The semiconductor memory device with a memory cell array includes a comparing circuit configured to compare data read after having been written for parallel bit testing with each other and outputting comparison result data; and a storage and output unit configured to latch, as pass/fail data, the comparison result data output from the comparing circuit, simultaneously output the latched comparison result data via a plurality of outputs when an enable signal is activated, and simultaneously output independently applied parallel bit test comparison data via the plurality of outputs when the enable signal is not activated.

### CROSS-REFERENCE TO RELATED APPLICATION

This application claims the benefit of Korean Patent Application No. 2007-0013159, filed Feb. 8, 2007, the disclosure of which is hereby incorporated herein by reference in its entirety.

### BACKGROUND OF THE INVENTION

1. Technical Field

The present invention relates to semiconductor memory devices, and more particularly, to a semiconductor memory device with a fail-bit storage unit and a method for parallel bit testing.

2. Discussion of Related Art

With the recent rapid development of information processing apparatuses such as computers, semiconductor memory devices for information processing apparatuses have gradually gained the features of high speed and high capacity.

In general, a testing burn-in process, which is a semiconductor post-process, is a process of eliminating initial device defects through low speed testing in which a memory device under test is laid in a high-temperature environment and a voltage or signal is applied to the device. To this end, the testing burn-in process requires a circuit for detecting a memory failure through low speed testing, and a fail-information storage device for storing failure information, which is processed and analyzed to reduce initial defects and improve productivity.

In the testing burn-in process, a memory device is inserted into a burn-in board (“BIB”) and burned in. A testing result is selected for each device under test (“DUT”) via an input/output (I/O) channel (48 bits) of the BIB.

The failure information includes a fail-bit count obtained by applying stress to the memory, reading input/output data, and counting a total number of fail bits at X and Y addresses of each DUT, and a fail-bit map for storing and mapping the X and Y addresses of the fail bits.

FIG. 1 is a schematic diagram illustrating a conventional board for parallel bit testing.

In FIG. 1, the testing board is formed on a PCB, and four DUTs 10, 11, 12, and 13 are connected to an external tester (not shown) via bus lines L1 to L4. In FIG. 1, data outputs DQ0 to DQ15 of the DUTs have a common wiring structure and each DUT is controlled individually via a chip select (CS) pin. That is, the data output DQ0 of the first DUT 10, the data output DQ0 of the second DUT 11, the data output DQ0 of the third DUT 12, and the data output DQ0 of the fourth DUT 13 are connected to one another and assigned, for example, to a first channel channel1 of the tester via the bus line L1. The data output DQ1 of the first DUT 10, the data output DQ1 of the second DUT 11, the data output DQ1 of the third DUT 12, and the data output DQ1 of the fourth DUT 13 are connected to one another and assigned, for example, a second channel channel 2 of the tester via the bus line L2.

In a write operation for parallel bit testing, the same data (x16) is applied to all four DUTs, so that the data is written to internal memory cells. In an actual testing operation, in which the written data is read and compared with each other, the tester reads latched pass/fail information from the device.

In the conventional structure as shown in FIG. 1, since the memory tester does not have a separate fail memory for parallel bit testing, there is no remaining LOG file containing past failure information as well as current failure information. Accordingly, as the latched pass/fail information is sequentially read using the same data output DQ, only a state of a currently enabled one of the DUTs can be recognized since there is no LOG file even though the chip select signals CS of the DUTs are separately enabled.

Since the data outputs DQ0, the data outputs DQ1, . . . , or the data outputs DQ15 of the four DUTs are assigned the same channel, it is impossible to identify a failing one of the DUTs.

### SUMMARY OF THE INVENTION

Exemplary embodiments of the present invention provide a semiconductor memory device having a memory cell array. The device includes a comparing circuit configured to compare data that are read after having been written for parallel bit testing with each other and to output comparison result data. The device also includes a storage and output unit configured to latch, as pass/fail data, the comparison result data output from the comparing circuit, to output the latched comparison result data simultaneously via a plurality of outputs if an enable signal is activated, and to output independently applied parallel bit test comparison data simultaneously via the plurality of outputs if the enable signal is not activated.

The storage and output unit may comprise a latch circuit, and the plurality of outputs may be set in units of four outputs per device under test. When a plurality of semiconductor memory devices are under test, the plurality of outputs may be assigned different channels of a tester. Chip select pins of the semiconductor memory devices may be individually controlled by the tester.

Other embodiments of the present invention provide a method for loading and testing a plurality of semiconductor memory devices each comprising a memory cell array, a comparing circuit, and a storage unit for storing pass/fail data. The method includes in one embodiment, writing the same logic data to the semiconductor memory devices at a time via input/output pins of the semiconductor memory devices; comparing, by the comparing circuit, data read from the respective memory cell arrays of the semiconductor memory devices with each other and outputting independent comparison result data; latching the comparison result data as pass/fail data; and detecting a failing one of the semiconductor memory devices by connecting the same input/output pins of the semiconductor memory devices to a tester via different channels, and simultaneously outputting the latched comparison result data via a plurality of outputs when a testing enable signal is activated.

According to the present invention, each device under test can be rapidly judged as pass or fail without a fail memory in the parallel bit tester. Therefore, semiconductor memory devices can be accurately judged as pass or fail without using expensive test equipment, thereby reducing manufacture cost.

### BRIEF DESCRIPTION OF THE DRAWINGS

The above and other features and advantages of the present invention will become more apparent to those of ordinary skill in the art by describing in detail example embodiments thereof with reference to the attached drawings in which:

FIG. 1 is a schematic diagram illustrating a conventional board for parallel bit testing;

FIG. 2 illustrates a portion of a conventional memory cell array structure;

FIG. 3 is a circuit diagram illustrating testing-related blocks in a semiconductor memory device according to an embodiment of the present invention;

FIG. 4 is a circuit diagram illustrating a reset signal generator for resetting a fail-bit storage unit of FIG. 3;

FIG. 5 is a timing diagram illustrating latch operation of a fail-bit storage unit in FIG. 2; and

FIG. 6 is a schematic diagram illustrating a read-related testing board for parallel bit testing according to an embodiment of the present invention.

### DETAILED DESCRIPTION OF THE INVENTION

Example embodiments will now be described more fully with reference to the accompanying drawings. However, example embodiments may be embodied in many different forms and should not be construed as being limited to the example embodiments set forth herein. Example embodiments are provided so that this disclosure will be thorough, and will fully convey the scope to those who are skilled in the art. In some example embodiments, well-known processes, well-known device structures, and well-known technologies are not described in detail to avoid the unclear interpretation of the example embodiments. Throughout the specification, like reference numerals in the drawings denote like elements.

It will be understood that when an element or layer is referred to as being “on”, “connected to” or “coupled to” another element or layer, it may be directly on, connected or coupled to the other element or layer, or intervening elements or layers may be present. In contrast, when an element is referred to as being “directly on,” “directly connected to” or “directly coupled to” another element or layer, there may be no intervening elements or layers present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Thus, a first element, component, region, layer or section discussed below could be termed a second element, component, region, layer or section without departing from the teachings of the example embodiments.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a”, “an” and “the” may be intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

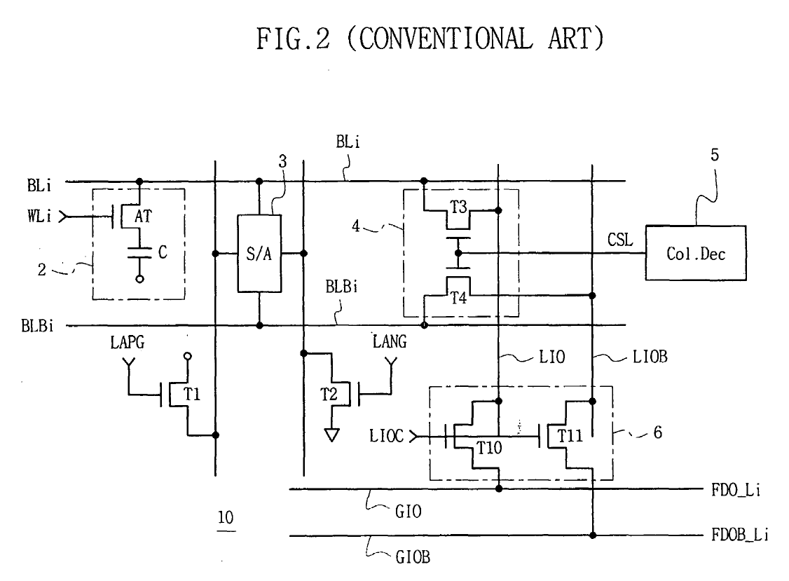

The present invention relates to a semiconductor memory device including a memory cell array. The memory cell array may be any well-known memory cell array. FIG. 2 illustrates a portion of a conventional memory cell array such as may be included in the semiconductor memory device. While a plurality of memory cells 2 are arranged in an array, FIG. 2 illustrates only one memory cell 2 for the sake of clarity. As shown, the memory cell 2 includes an access transistor AT connected in series with a capacitor C between a bit line BLi and a reference voltage (e.g., ground). A gate of the access transistor AT is connected to a word line WLi. Based on the voltage applied to the word line WLi, the bit line BLi becomes connected to the capacitor C. In this manner a charge on the bit line may be stored in the capacitor C, or alternatively, a charge stored in the capacitor C may be read out on the bit line. A sense amplifier 3 sense amplifies the voltage difference between the bit line BLi and complementary bit line BLBi. The bit and complementary bit lines BLi and BLBi are selectively connected to local data input/output lines LIO and LIOB, respectively, by a column selector 4 in response to a column select signal from a column decoder 5. A global data output unit 6 selectively connects the local data input/output lines LIO and LIOB to global data input/output lines GIO and GIOB, respectively. During a read operation, for example, the charge stored in the capacitor C may be sense amplified and output as output signals FDO_Li and FDOB_Li. Because the operation and detailed structure of the memory cell is so well-known, a more detailed description thereof will be omitted for the sake of brevity.

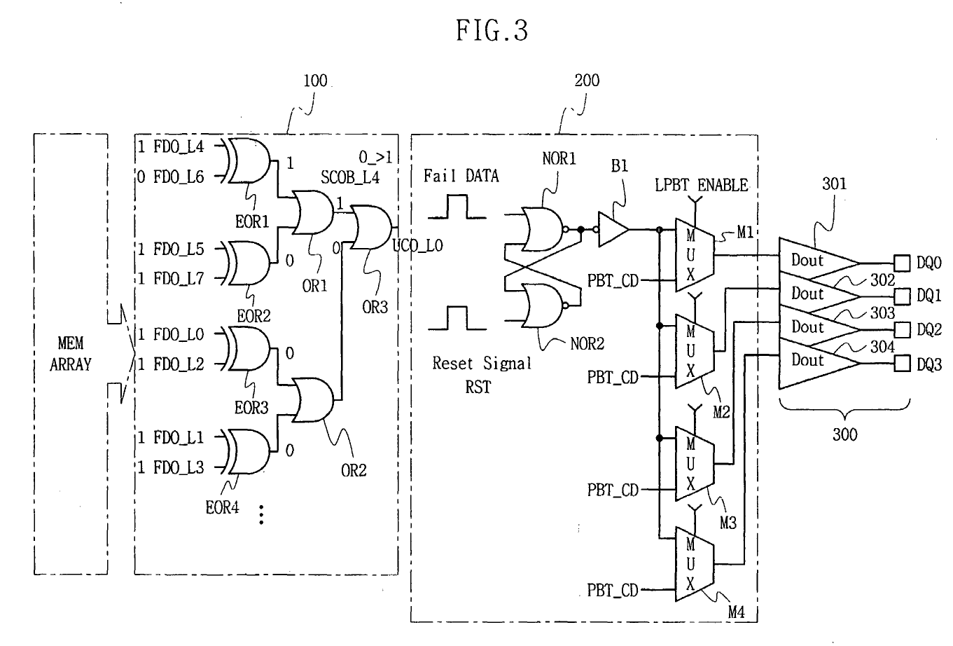

FIG. 3 is a circuit diagram illustrating testing-related blocks in the semiconductor memory device according to an embodiment of the present invention.

Referring to FIG. 3, a comparing circuit 100, a storage and output unit 200, and an output driving unit 300 are shown.

The comparing circuit 100 comprises exclusive OR gates EOR1 to EOR4 connected to the memory cell array 10 of FIG. 2 and OR gates OR1, OR2, and OR3. In this example, the memory cell array 10 generates eight output signals FDO_L0 through FDO_L7 during a read operation. These output signals are the read data. The comparing circuit 100 compares the data read, after being written for parallel bit testing, with each other; and outputs comparison result data. In particular, the exclusive OR gate EOR1 exclusive ORs the fifth and seventh output signals FDO_L4 and FDO_L6. The exclusive OR gate EOR2 exclusive ORs the sixth and eighth output signals FDO_L5 and FDO_L7. The exclusive OR gate EOR3 exclusive ORs the first and third output signal FDO_LO and FDO_L2. A first OR gate OR1 ORs the output of the first and second exclusive OR gates EOR1 and EOR2. A second OR gate OR2 ORs the output of the third and fourth exclusive OR gates EOR3 and EOR4. A third OR gate OR3 ORs the output of the first and second OR gates OR1 and OR2 to generate comparison result data UCO_LO.

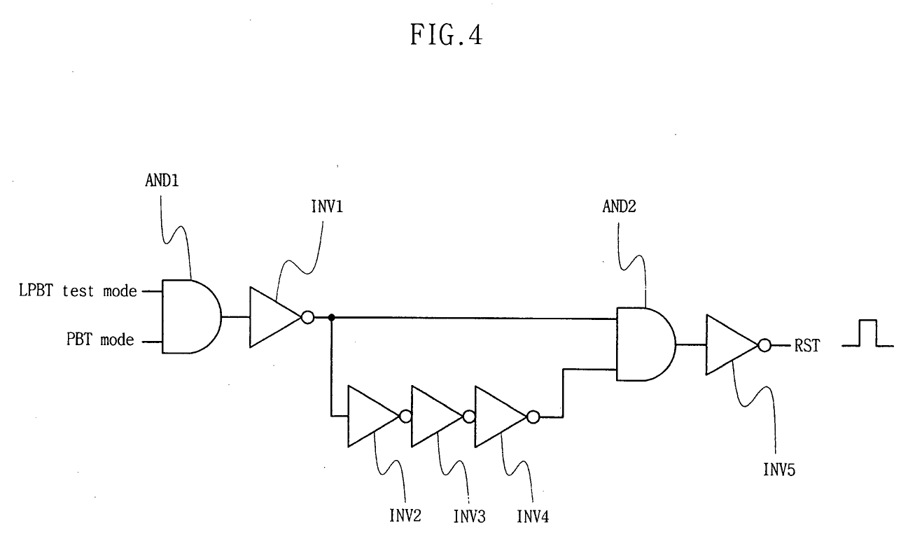

The storage and output unit 200 comprises NOR gates NOR1 and NOR2, which constitute a latch, a buffer B1, and multiplexers M1 to M4. The storage and output unit 200 latches, as pass/fail data, the comparison result data UCO_L0 output from the comparing circuit 100. When an enable signal LPBT ENABLE output from a tester is activated, the storage and output unit 200 simultaneously outputs the latched comparison result data via a plurality of outputs DQ0-DQ3. When the enable signal LPBT ENABLE is not activated, the storage and output unit 200 simultaneously outputs parallel bit test comparison data PBT_CD, independently applied by the tester, via the plurality of outputs DQ0 to DQ3. The latch constituted by the NOR gates NOR1 and NOR2 is reset by a reset signal RST described in detail below with respect to FIG. 4.

Although four outputs have been shown by way of example in FIG. 3, it will be easily appreciated that the outputs may increase or decrease, if necessary.

In FIG. 3, the comparing circuit 100 is used for implementation of latched parallel bit test (LPBT). In a first case, for PBTx1, comparison data is output at DQ0, and for PBTx4, comparison data is output at DQ0 to DQ3. In the LPBT test mode of the present invention, DQ0 to DQ7 data are compared with one another to obtain 1-bit fail data at a PBTx8 state, and. DQ0 to DQ3 data are compared with each other to obtain 1-bit fail data at a PBTx4 state. The obtained 1-bit fail data is stored in a latch, which functions as a fail-bit storage unit in the storage and output unit 200. The stored fail data is output at the same logic state to DQ0 to DQ3 via the four multiplexers (M1 to M4) only when the LPBT mode is enabled. When the LPBT mode is not enabled, an existing PBT data values are output independently via the multiplexers. As a result, with the circuit as shown in FIG. 3, 1-bit fail/pass data is output to the data outputs DQ0 to DQ3 via all the four multiplexers when the LPBT test mode is enabled.

The tester compares the data received via the four channels, which are differently assigned. Namely, when a plurality of semiconductor memory devices each having the functional blocks as shown in FIG. 3 are under test, the plurality of outputs of the DUTs are assigned to different channels of the tester. That is, among the DUTs, the data output DQ0 of a first DUT is assigned to a first channel of the tester, the data output DQ1 of a second DUT is assigned to a second channel of the tester, the data output DQ2 of a third DUT is assigned to a third channel of the tester, and the data output DQ3 of a fourth DUT is assigned to a fourth channel of the tester. In this case, chip select pins of the DUTs are individually controlled by the tester. Therefore, the tester can easily recognize a fail DUT when fail bit information are received via the first to fourth channels. When any one of the data differs from others, a corresponding DUT is easily detected as a fail DUT by the tester.

FIG. 4 is a circuit diagram illustrating a reset signal generator for resetting a fail-bit storage unit of FIG. 3. An AND gate AND1 receives a LPBT test mode signal and a PBT mode signal output from the tester and generates an AND response. The LPBT test mode signal and the PBT mode signal are test mode information generated externally by a parallel bit tester and applied to the semiconductor memory device. An inverter INV1 inverts the AND response. An AND gate AND2 receives an output of the inverter INV1 and an output of a delay chain including inverters INV2 to INV4 and generates an AND response. Here, the AND response generated by the AND gate AND2 is in the form of a short pulse, and is inverted again by an driving inverter INV5. The inverter INV5 outputs a high-level short pulse, which is a desired reset signal RST. The latch consisting of the NOR gates NOR1 and NOR2 of FIG. 2 is reset by the reset signal RST.

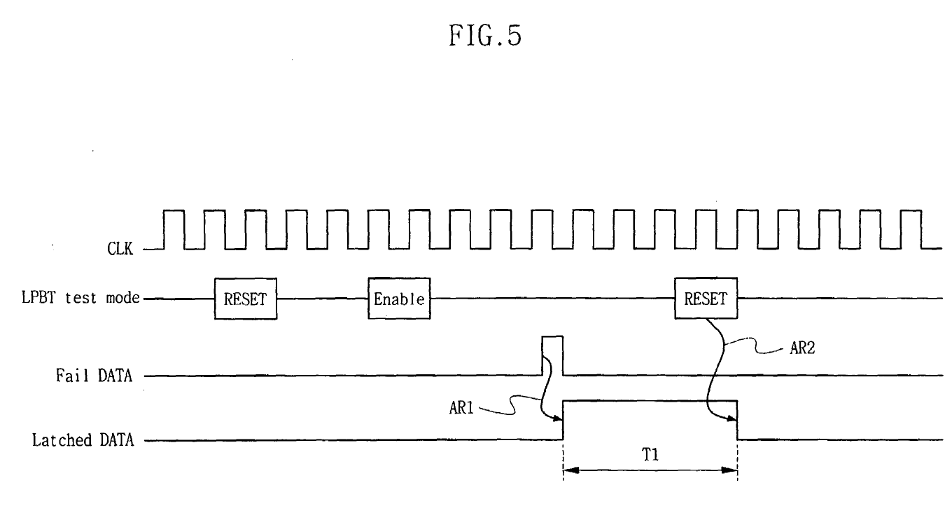

FIG. 5 is a timing diagram illustrating latch operation of the fail-bit storage unit in FIG. 3. Referring to FIG. 5, a latch section T1 is shown. After the latch is initialized by an initially generated reset signal, the LPBT test mode is enabled so that the PBT is performed. When fail data is generated as in the timing diagram of FIG. 5 in the PBT, the latch latches the data for a latch section T1, as indicated by an arrow AR1. The latch is then reset and initialized as indicated by an arrow AR2. In FIG. 5, CLK denotes a system clock of the semiconductor memory device.

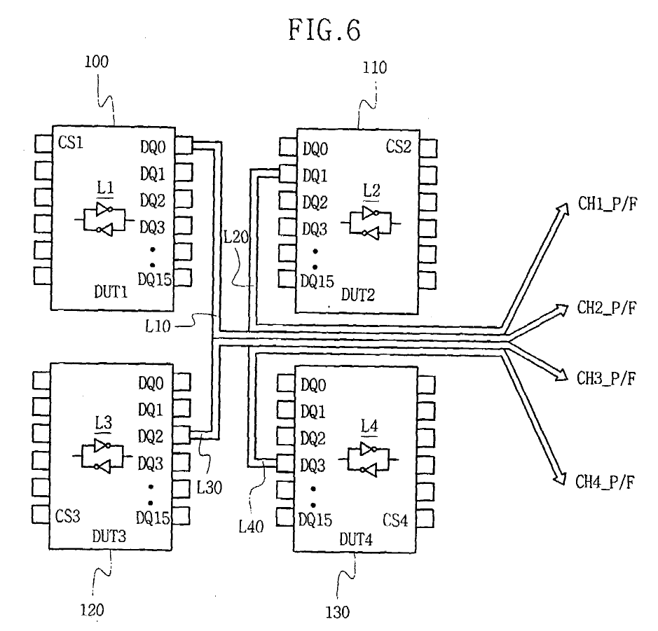

The structure of the semiconductor memory device has been described with reference to FIGS. 3 to 5. Now, a configuration of the testing board will be described with reference to FIG. 6.

FIG. 6 is a schematic diagram illustrating a read-related testing board for parallel bit testing according to the present invention.

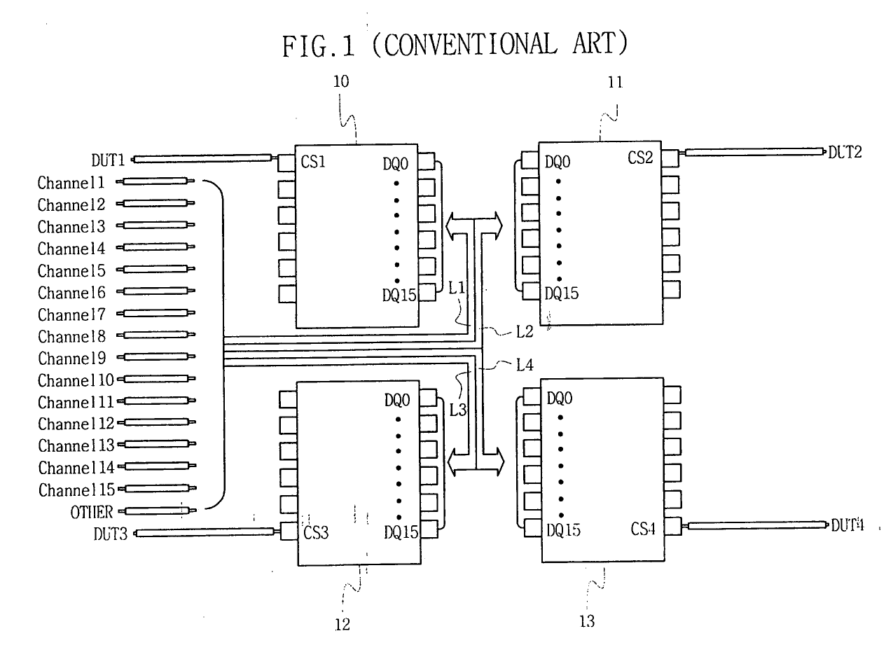

It is noted that a channel structure in a read mode of operation for detecting a fail bit, not in a write mode of operation for parallel bit testing, is shown in FIG. 6. In the write mode of operation, all DUTs are wired as shown in FIG. 1, and the same test write data is applied in predetermined bits (e.g., x16 bits) to all the DUTs.

In the read mode of operation for parallel bit testing, a result of comparing outputs DQ0 to DQ15 with each other is output through four outputs DQ of each DUT. The tester has H/W channels separately assigned to the respective DUTs to perform pass/fail judgment. That is, for the outputs DQ0 to DQ15 of the first DUT 100, an output DQ0 as a representative is assigned the first channel; for the outputs DQ0 to DQ15 of the second DUT 110, the output DQ1 as a representative is assigned the second channel; for the outputs DQ0 to DQ15 of the third DUT 120, the output DQ2 as a representative is assigned the third channel; and for the outputs DQ0 to DQ15 of the fourth DUT 130, the output DQ3 as a representative is assigned the fourth channel. The tester compares data on the four channels. When at least one of the channel data differs from others, the tester detects a corresponding DUT as a fail DUT. As a result, a fail one of the four DUTs can be detected without a separate fail memory in the parallel bit tester.

In FIG. 6, each DUT has the four outputs DQ0 to DQ3, each DUT is assigned a different channel, and each DUT has an individually controlled CS pin. Accordingly, the tester can read the data stored in the latch after parallel bit testing and judge each DUT as pass or fail.

As a result, in the embodiment of the present invention, the pass/fail data of the DUTs are simultaneously output via for example four outputs DQ, and the different outputs of the DUTs are assigned separate hardware channels to perform pass/fail judgment. Thus, a fail DUT can be easily detected.

As described above, according to the present invention, each device under test can be rapidly judged as pass or fail without using a fail memory in the parallel bit tester. Therefore, semiconductor memory devices can be accurately judged as pass or fail without using expensive test equipment, thereby reducing manufacture cost.

The invention has been described using exemplary embodiments. However, it is to be understood that the scope of the invention is not limited to the disclosed embodiments. On the contrary, the scope of the invention is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements. For example, the latch circuit for storing the fail-bit information may be modified, the number of the outputs may be changed, or a testing order or operation timing may be changed.

What is claimed is:

1. A semiconductor memory device comprising a memory cell array, the device comprising:
a comparing circuit configured to compare data read after having been written for parallel bit testing and outputting comparison result data; and
a storage and output unit configured to latch, as pass/fail data, the comparison result data output from the comparing circuit, to output the latched comparison result data simultaneously via a plurality of outputs if an enable signal is activated, and to output independently applied parallel bit test comparison data simultaneously via the plurality of outputs when the enable signal is not activated.

2. The device according to claim 1, wherein the storage and output unit comprises a latch circuit.

3. The device according to claim 2, wherein the plurality of outputs is four.

4. A clock synchronous semiconductor memory device comprising an information storage unit configured to store pass/fail information for memory cells upon parallel bit testing in which a plurality of data are simultaneously output from the memory cells, compared with each other, and externally output based on the comparison.

5. A method for loading and testing a plurality of semiconductor memory devices each comprising a memory cell array, a comparing circuit, and a storage unit for storing pass/fail data, the method comprising:
writing the same logic data to the semiconductor memory devices at a time via input/output pins of the semiconductor memory devices;
comparing, by the comparing circuit, data read from the respective memory cell arrays of the semiconductor memory devices with each other and outputting independent comparison result data;
latching the comparison result data as pass/fail data; and
detecting a fail one of the semiconductor memory devices by connecting the same input/output pins of the semiconductor memory devices to a tester via different channels, and simultaneously outputting the latched comparison result data via a plurality of outputs when a testing enable signal is activated.
